(19) United States
(12) Patent Application Publication
(10) Pub. No.: US 2011/0308565 A1
(43) Pub. Date: Dec. 22, 2011

(54) SOLAR CELL MODULE AND METHOD FOR MANUFACTURING THE SAME

(75) Inventors: Michihiro Takayama, Chigasaki-shi (JP); Yuko Taguchi, Chigasaki-shi (JP); Hiroki Takanashi, Chigasaki-shi (JP); Toshihide Okatsu, Chigasaki-shi (JP); Hiroto Uchida, Chigasaki-shi (JP)

(73) Assignee: ULVAC, INC., Chigasaki-shi (JP)

(21) Appl. No.: 13/146,590

(22) PCT Filed: Mar. 10, 2010
(86) PCT No.: PCT/JP2010/001699

§ 371 Date: Jul. 27, 2011

(30) Foreign Application Priority Data
Mar. 10, 2009 (JP) P2009-056777

(51) Int. Cl. H01L 31/05; H01L 31/18

(52) U.S. Cl. 136/244; 438/80; 257/E31.11

(57) ABSTRACT

A solar cell module includes: a plurality of photovoltaic cells including a layered body in which a first electrode layer, a power generation layer, and a second electrode layer are layered in series, the photovoltaic cells being electrically connected with each other in series; a scribe line separating the photovoltaic cells that are adjacent to each other in the photovoltaic cells; a scribe hole that is formed so as to penetrate through the power generation layer and the second electrode layer; and a bypass pathway that is formed of a shunt region, the shunt region being generated at a periphery of the scribe hole.

### BACKGROUND OF THE INVENTION

1. Field of the Invention

The present invention relates to a solar cell module and a method for manufacturing the same.

This application claims priority from Japanese Patent Application No. 2009-056777 filed on Mar. 10, 2009, the contents of which are incorporated herein by reference in their entirety.

2. Background Art

In recent years, in view of efficient use of energy, solar cells have been more widely used than ever before.

Specifically, a solar cell in which a silicon single crystal is utilized has a high level of energy conversion efficiency per unit area.

However, in contrast, in the solar cell in which the silicon single crystal is utilized, a silicon single crystal ingot is sliced, and a sliced silicon wafer is used in the solar cell; therefore, a large amount of energy is spent for manufacturing the ingot, and the manufacturing cost is high.

Specifically, at the moment, in a case of realizing a solar cell having a large area which is placed out of doors or the like, when the solar cell is manufactured by use of a silicon single crystal, the cost considerably increases.

Consequently, as a low-cost solar cell, a solar cell that can be further inexpensively manufactured and that employs a thin film made of amorphous silicon is in widespread use.

An amorphous silicon solar cell uses semiconductor films of a layered structure that is referred to as a pin-junction in which an amorphous silicon film (i-type) is sandwiched between p-type and n-type silicon films, the amorphous silicon film (i-type) generating electrons and holes when receiving light.

An electrode is formed on both faces of the semiconductor films.

The electrons and holes generated by sunlight actively transfer due to a difference in the electrical potentials between p-type and n-type semiconductors, and a difference in the electrical potentials between both faces of the electrodes is generated when the transfer thereof is continuously repeated.

As a specific structure of the amorphous silicon solar cell as described above, for example, a structure is employed in which a transparent electrode is formed as a lower electrode by forming TCO (Transparent Conductive Oxide) or the like on a glass substrate, and a semiconductor film composed of amorphous silicon and an upper electrode that becomes an Ag thin film or the like are formed thereon.

In the amorphous silicon solar cell that is provided with a photoelectric converter constituted of the foregoing upper and lower electrodes and the semiconductor film, the difference in the electrical potentials is small if each of the layers having a large area is only uniformly formed on the substrate, and there is a problem in that the resistance increases.

Consequently, the amorphous silicon solar cell is formed by, for example, forming photovoltaic cells so as to electrically separate the photoelectric converter by a predetermined size, and by electrically connecting adjacent photovoltaic cells with each other.

Specifically, a structure is adopted in which a groove that is referred to as a scribe line (scribing line) is formed on the photoelectric converter having a large area uniformly formed on the substrate by use of a laser light or the like, a plurality of photovoltaic cells formed in a longitudinal rectangular shape is obtained, and the photovoltaic cells are electrically connected in series.

Meanwhile, in a thin-film silicon solar cell in which the photovoltaic cells are connected to each other in series, when output (production of electricity) of a part of the photovoltaic cells decreases, the output of the entirety of the thin-film silicon solar cell module is significantly degraded.

For example, in a step of manufacturing photovoltaic cells, when particles are mixed therein, when an electrode is non-uniformly formed, when a defect is generated in an electrode, when contaminants land on a light incident face, or when a light incident face is shaded, the total output of the thin-film silicon solar cell module becomes degraded.

Furthermore, a photovoltaic cell in which the output thereof is degraded becomes electrical resistance in the series circuit which is constituted of a plurality of photovoltaic cells, and a voltage (bias voltage) is applied to both ends of the photovoltaic cell in an inverse direction.

In this case, an electrical current concentrates in the defect portion in the photovoltaic cell, and local heat phenomenon (hot spot phenomenon) is generated.

As a result of the foregoing locally generated heat, there is a problem in that the photovoltaic power of the photovoltaic cell is lost, and the photovoltaic cell is broken down.

Conventionally, in order to avoid the degradation of output and the hot spot phenomenon, a method is known which decreases the voltage to be applied to the photovoltaic cell in which the photovoltaic power thereof is lost by connecting a bypass diode to a thin-film silicon solar cell module in parallel, and which prevents the photovoltaic cell in which the photovoltaic power is lost from being broken (for example, refer to Japanese Unexamined Patent Application, First Publication No. 2001-068696).

Furthermore, a technique of providing a partial scribe line in parallel to a scribe line is known (for example, refer to Japanese Unexamined Patent Application, First Publication No. 2002-76402 or the like).

However, in such the above techniques, the number of steps of manufacturing increases, and there is a problem in that, for example, the cost thereof increases due to connection of a plurality of bypass diodes to the module in parallel.

### SUMMARY OF THE INVENTION

The invention was made in order to solve the above problems, and has a first object to provide a solar cell module which does not need a complicated structure, which can prevent a hot spot phenomenon and which possesses excellent reliability.

Additionally, the invention has a second object to provide a manufacturing method which can be used in the apparatus which has been already installed without increasing the number of the steps of manufacturing solar cell modules. The method can reduce the cost thereof and prevent a hot spot phenomenon. The method can manufacture a solar cell module possessing excellent reliability.

A solar cell module of a first aspect of the invention includes: a plurality of photovoltaic cells including a layered body in which a first electrode layer, a power generation layer, and a second electrode layer are layered in series, the photovoltaic cells being electrically connected with each other in series; a scribe line separating the photovoltaic cells that are adjacent to each other in the photovoltaic cells; a laser scribe hole that is formed so as to penetrate through the power generation layer and the second electrode layer; and a bypass pathway that is formed of a shunt region, the shunt region being generated at the periphery of the laser scribe hole.

It is preferable that the solar cell module of the first aspect of the invention include a plurality of laser scribe holes that are formed so as to penetrate through the power generation layer and the second electrode layer.

Here, the direction in which the laser scribe holes are arrayed may be parallel to the scribe line, may be the direction which is orthogonal to the scribe line, may be the direction which intersects with the scribe line by a predetermined angle.

A solar cell module manufacturing method of a second aspect of the invention includes: forming a layered body in which a first electrode layer, a power generation layer, and a second electrode layer are layered in series on a substrate; forming a plurality of photovoltaic cells which are electrically connected in series by forming a scribe line; forming a scribe hole that penetrates through the power generation layer and the second electrode by irradiating a part of the power generation layer and the second electrode layer with a laser light; and forming a bypass pathway including a shunt region which is generated at a processed edge face of the power generation layer and the second electrode layer using heat, the heat being generated at the time of the laser light irradiation.

In addition, “solar cell module” of the invention is not limited to a single cell having a single power generation layer, and also includes a multi-junction cell in which a plurality of power generation layers are layered.

Moreover, “processed edge face” is a face which is substantially parallel to the irradiation direction of a laser light.

Furthermore, the shunt region is a region which is formed from the processed edge face toward the inside of the power generation layer and the second electrode layer in the direction parallel to the substrate.

The foregoing shunt region is formed near the processed edge face. The shunt region has a predetermined depth in the direction parallel to the substrate.

In the shunt region, the first electrode layer is connected to the second electrode layer with an electrical resistance which is lower than that of the power generation layer, or the first electrode layer, the power generation layer, and the second electrode layer are electrically short-circuited.

### Effects of the Invention

The solar cell module of the invention includes the laser scribe hole which is formed so as to penetrate through the power generation layer and the second electrode layer.

Because of this, even when the output decreases due to occurrence of malfunction in one of the photovoltaic cells, since the shunt region which is generated around the laser scribe hole is operates as a bypass pathway, it is possible for an electrical current to flow in the bypass pathway.

Consequently, the voltage to be applied to the photovoltaic cell in which the output thereof is lowered decreases, and it is possible to prevent the photovoltaic cell in which the output thereof is lowered from breaking down.

As a result, in the solar cell module of the invention, a complicated structure is not necessary, it is possible to prevent a hot spot phenomenon from being generated, and it is possible to provide a solar cell module possessing excellent reliability.

In the solar cell module of the invention, a part of the power generation layer and the second electrode layer is removed by irradiation of a laser light, and the laser scribe hole is thereby formed.

In the resultant solar cell module by use of this method, the shunt region is formed at the processed edge face of the power generation layer and the second electrode layer by the heat which is generated at the time of forming the laser scribe hole.

As a result, in the solar cell module manufacturing method of the invention, the method can be used in the apparatus which has been already installed without increasing the number of the steps thereof.

It is possible to reduce the cost thereof, prevent a hot spot phenomenon, and manufacture a solar cell module possessing excellent reliability.

### BRIEF DESCRIPTION OF THE DRAWINGS

FIG. 1 is an enlarged perspective view showing a solar cell module related to an embodiment of the invention.

FIG. 2A is a cross-sectional view showing the solar cell module shown in FIG. 1.

FIG. 2B is an enlarged cross-sectional view showing the solar cell module shown in FIG. 2A.

FIG. 2C is a cross-sectional view showing the solar cell module shown in FIG. 1.

FIG. 3A is a cross-sectional view showing a solar cell module manufacturing method.

FIG. 3B is a cross-sectional view showing the solar cell module manufacturing method.

FIG. 3C is a cross-sectional view showing the solar cell module manufacturing method.

FIG. 3D is a cross-sectional view showing the solar cell module manufacturing method.

FIG. 3E is a cross-sectional view showing the solar cell module manufacturing method.

FIG. 3F is a cross-sectional view showing the solar cell module manufacturing method.

### DESCRIPTION OF THE PREFERRED EMBODIMENTS

Hereinafter, an embodiment of a solar cell module and a manufacturing method the same related to the invention will be described with reference to drawings.

In the respective drawings, in order to make the respective components be of understandable size in the drawing, the dimensions and the proportions of the respective components are modified as needed compared with the real components.

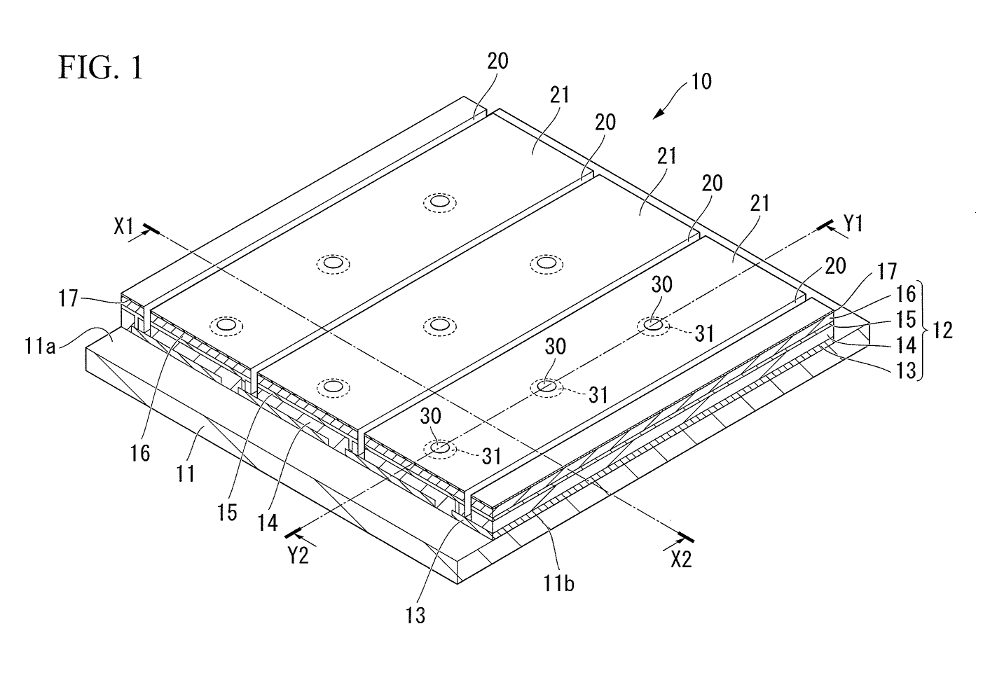

FIG. 1 is an enlarged perspective view showing an amorphous silicon solar cell module of an embodiment related to the invention.

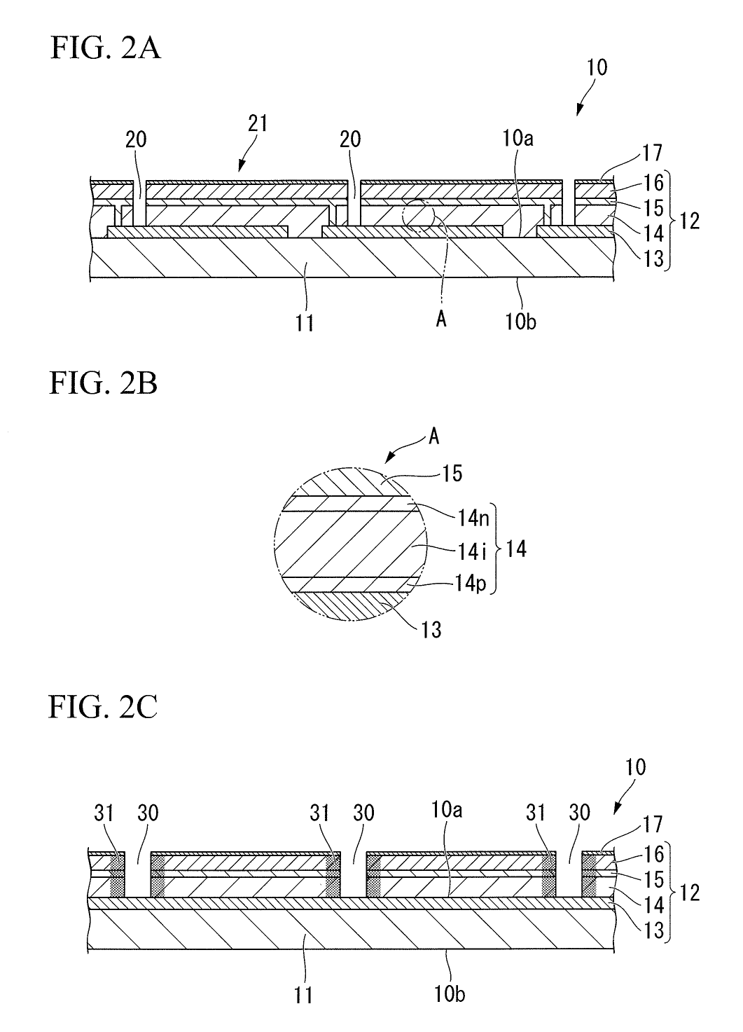

FIGS. 2A to 2C are cross-sectional views showing a layer structure of the solar cell module of FIG. 1.

FIG. 2A is a cross-sectional view taken along the line X1-X2 of FIG. 1.

FIG. 2B is an enlarged cross-sectional view showing the portion indicated by reference numeral A in FIG. 2A.

FIG. 2C is a cross-sectional view taken along the line Y1-Y2 of FIG. 1.

A solar cell module 10 of the embodiment includes a structure in which a plurality of photovoltaic cells 21 that are electrically connected in series are formed on a first face 11a of a substrate 11.

The photovoltaic cell 21 includes a layered body 12 in which a first electrode layer 13, a power generation layer 14, a buffer layer 15, and a second electrode layer 16 are layered in this order.

Among the photovoltaic cells 21, a scribe line 20 is formed at the photovoltaic cells adjacent to each other.

The scribe line 20 is formed on the first electrode layer 13, therefore, the photovoltaic cells 21 are separated.

In the solar cell module 10 of the embodiment, laser scribe holes 30 (scribe hole) are formed so as to penetrate through the power generation layer 14, the buffer layer 15, and the second electrode layer 16.

A shunt region 31 is generated at the periphery of a laser scribe hole 30, and a bypass pathway formed by the shunt region 31 is provided thereat.

Because of this, even when the output decreases due to occurrence of malfunction in one of the photovoltaic cells, since the shunt region 31 which is generated around the laser scribe hole 30 is operates as a bypass pathway, it is possible for an electrical current to flow in the bypass pathway.

Consequently, the voltage to be applied to the photovoltaic cell in which the output thereof is lowered decreases, and it is possible to prevent the photovoltaic cell in which the output thereof is lowered from being broken down.

As a result, in the solar cell module 10 of the embodiment, a complicated structure is not necessary, it is possible to prevent a hot spot phenomenon from being generated, and it is possible to obtain an excellent reliability thereof.

The substrate 11 is formed of an insulation material having a high level of sunlight transparency and durability such as a glass or a transparent resin.

In the solar cell module 10, sunlight S is incident to a second face 11b of the substrate 11 which is opposite to the first face 11a.

In the layered body 12, the first electrode layer (lower electrode) 13, the power generation layer 14 (semiconductor layer) 14, the buffer layer 15, and the second electrode layer (upper electrode) 16 are sequentially layered on the first face 11a of the substrate 11.

The first electrode layer 13 (lower electrode) is formed of a transparent electroconductive material, for example, a metal oxidative product having an optical transparency such as SnO₂, ITO, ZnO, or the like.

The power generation layer 14 (semiconductor layer) has a pin-junction structure in which, for example, an i-type amorphous silicon film 14i is sandwiched between a p-type amorphous silicon film 14p and an n-type amorphous silicon film 14n as shown in FIG. 2B.

When sunlight is incident to the power generation layer 14, electrons and holes are generated, and electrons and holes are activated between the p-type amorphous silicon film 14p and the n-type amorphous silicon film 14n.

A difference in the electrical potentials between the first electrode layer 13 and the second electrode layer 16 is generated when the above-described action is continuously repeated (photoelectric conversion).

Additionally, it is preferable that the buffer layer 15 be disposed between the power generation layer 14 and the second electrode layer 16 formed above the power generation layer 14.

Due to the buffer layer 15 being disposed between the power generation layer 14 and the second electrode 16, it is possible to reduce silicon diffusing in the power generation layer 14 from the second electrode 16 and to inhibit the reaction thereof.

A material used to form the foregoing buffer layer 15 is, for example, ZnO or the like.

The second electrode layer 16 (upper electrode) is formed of a light reflection film possessing electroconductivity such as Ag (silver), Al (aluminum), or the like.

It is possible to form the second electrode layer 16 using a film formation method of, for example, a sputtering or the like.

The foregoing layered body 12 is separated into a plurality of layered bodies by forming the scribe line 20.

Because of this, for example, a plurality of photovoltaic cells 21 whose external form is a longitudinal rectangular shape are formed on the substrate 11a.

Each of the photovoltaic cells 21 is electrically separated, and adjacent photovoltaic cells 21 are electrically connected together in series.

In the foregoing constitution, all of photovoltaic cells 21 having the aforementioned layered body 12 are electrically connected together in series.

For this reason, it is possible to obtain electrical power in which the difference in the electrical potentials is large and the amount of electrical current is large.

The scribe line 20 is formed by irradiating the layered body 12 with a laser light or the like after, for example, the layered body 12 is uniformly formed on the first face 11a of the substrate 11.

Therefore, a groove having a predetermined distance is formed on the layered body 12.

Specifically, in the solar cell module 10 of the embodiment as shown in FIGS. 1 and 2C, a plurality of laser scribe holes 30 are formed so as to penetrate through the power generation layer 14, the buffer layer 15, and the second electrode layer 16.

The shunt regions 31 are generated at the periphery of laser scribe holes 30, therefore, bypass pathways are provided.

As shown in FIG. 1, the laser scribe holes 30 are arrayed on a line parallel to the scribe line 20.

In a conventional photovoltaic cell, when contaminants land on a light incident face (second face 11b) or when the light incident face is shaded, the total output of the solar cell module becomes degraded.

Furthermore, a photovoltaic cell in which the output thereof is degraded becomes electrical resistance in the series circuit which is constituted of a plurality of photovoltaic cells, and a voltage (bias voltage) is applied to both ends of the photovoltaic cell in an inverse direction.

In this case, an electrical current concentrates in the defect portion in the photovoltaic cell, and local heat phenomenon (hot spot phenomenon) is generated.

In contrast, since the shunt region 31 functions as a bypass pathway in the solar cell module 10 of the embodiment, it is possible to suppress all of the inverted voltage generated in the photovoltaic cell from being locally concentrated.

As a result, it is possible to prevent a hot spot from being formed.

The invention does not limit positions at which the laser scribe holes 30 are to be formed, the shape of the laser scribe hole 30, the size of the laser scribe hole 30, or the like.

The fill factor (FF) of a solar cell may be degraded depending on the conditions of forming a laser scribe hole 30 in the step thereof.

When, for example, the number of the scribe holes 30 increases more than necessary, the characteristics thereof are degraded.

For this reason, in order to obtain resistance to hot spot, it is preferable that the number of the scribe holes 30 and the positions at which the laser scribe holes 30 are to be formed be determined so that FF value becomes the range of, for example, FF≧0.60.

Specifically, it is preferable that, for example, the laser scribe holes 30 be formed on the layered body 12 and the scribe holes be arrayed in a linear orientation.

Therefore, without degradation of the characteristics, it is possible to effectively minimize formation of a hot spot.

Next, a method for manufacturing the solar cell module 10 having the above-described constitution will be described.

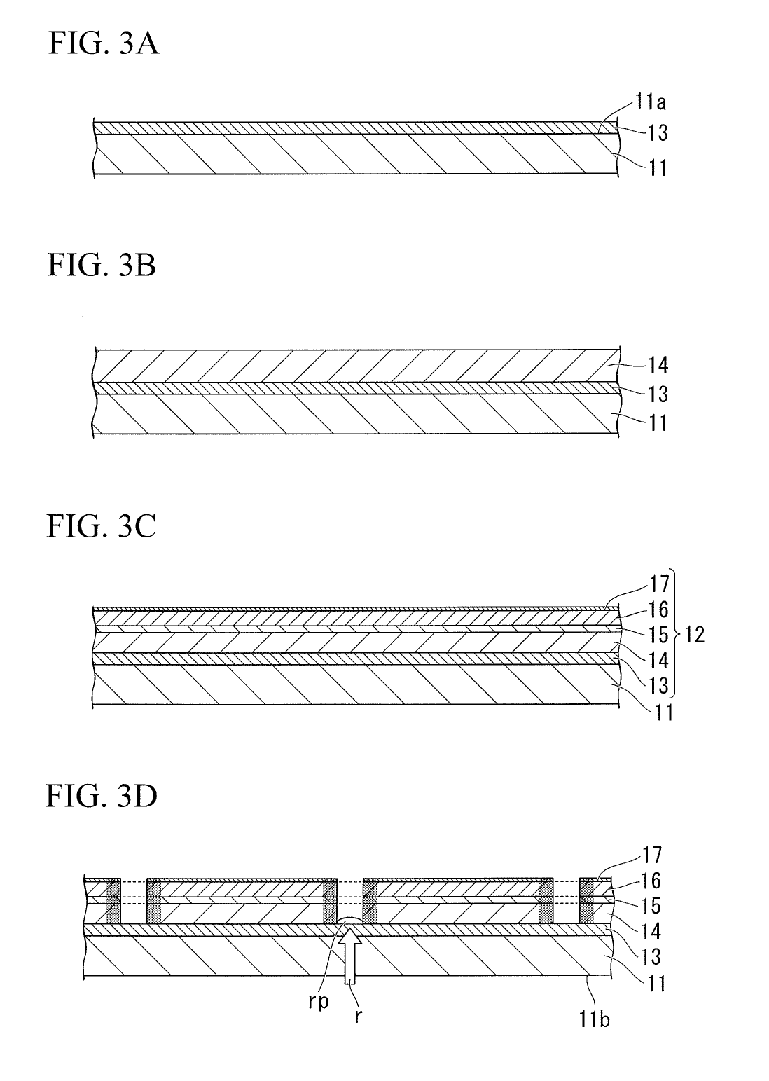

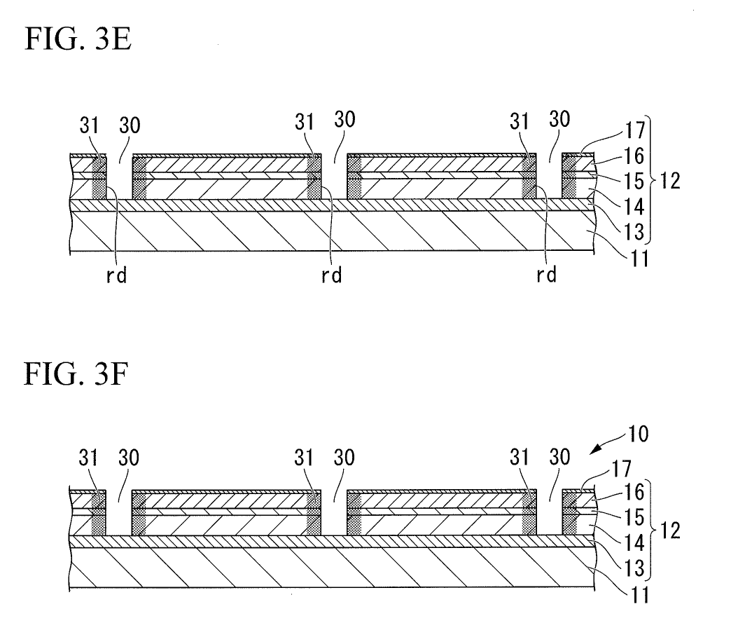

FIGS. 3A to 3F are cross-sectional views showing sequential steps of a solar cell module manufacturing method related to the invention.

Each of FIGS. 3A to 3F corresponds to a cross-sectional view taken along the line Y1-Y2 of FIG. 1.

In the solar cell module manufacturing method of the embodiment, a part of the power generation layer 14, the buffer layer 15, and the second electrode layer 16 is removed by irradiation of a laser light, and the laser scribe holes 30 are thereby formed.

Furthermore, by use of heat which is generated at the time of laser light irradiation, a shunt region 31 is generated at a processed edge face rd of the power generation layer 14, the buffer layer 15, and the second electrode layer 16.

The shunt region 31 functions as a bypass pathway.

As a result, in the solar cell module manufacturing method of the embodiment, the method can be used in the apparatus which has been already installed without increasing the number of the steps of manufacturing solar cell modules. It is possible to reduce the cost thereof, prevent a hot spot phenomenon, and manufacture a solar cell module 10 possessing excellent reliability.

As described below, the steps will be sequentially described.

(1) Firstly, a substrate 11 is prepared.

The substrate 11 is formed of an insulation material having a high level of sunlight transparency and durability such as a glass or a transparent resin.

(2) Next, as shown in FIG. 3A, a first electrode layer 13 is formed on a first face 11a of the substrate 11.

The first electrode layer 13 is a TCO electrode which is formed of a metal oxidative product having optical transparency, TCO (Transparent Conducting Oxide) such as, for example, AZO (Al-added ZnO), GZO (Ga-added ZnO), ITO (Indium Tin Oxide), or the like.

(3) Next, as shown in FIG. 3B, a p-type amorphous silicon film 14p, an i-type amorphous silicon film 14i, and an n-type amorphous silicon film 14n of the power generation layer 14 are formed on the first electrode layer 13 (refer to FIG. 2B).

Each of the films 14p, 14i, and 14n is formed in a plasma CVD reaction chamber for exclusive use, in which each film is formed.

The p-type amorphous silicon film 14p is formed in a reaction chamber using a plasma CVD method.

In the condition for forming the film, for example, the substrate temperature is 180 to 200° C., power supply frequency is 13.56 MHz, and the inner pressure of the reaction chamber is 70 to 120 Pa.

Additionally, regarding the conditions of the flow rates of reactive gases, monosilane (SiH₄) is 300 sccm, hydrogen (H₂) is 2300 sccm, diborane (B₂H₆/H₂) including hydrogen as a diluted gas is 180 sccm, and methane (CH₄) is 500 sccm.

The i-type amorphous silicon film 14i is formed in a reaction chamber, using a plasma CVD method.

In the condition for forming the film, for example, the substrate temperature is 180 to 200° C., power supply frequency is 13.56 MHz, and the inner pressure of the reaction chamber is 70 to 120 Pa.

Additionally, regarding the condition of the flow rate of reactive gas, monosilane (SiH₄) is 1200 sccm.

The n-type amorphous silicon film 14n is formed in a reaction chamber, using a plasma CVD method.

In the condition for forming the film, for example, the substrate temperature is 180 to 200° C., power supply frequency is 13.56 MHz, and the inner pressure of the reaction chamber is 70 to 120 Pa.

Additionally, regarding the condition of the flow rate of reactive gas, phosphine (PH₃/H₂) including hydrogen as a diluted gas is 200 sccm.

(4) Next, as shown in FIG. 3C, the buffer layer 15 and the second electrode 16 are sequentially formed on the power generation layer 14 using a sputtering method.

The buffer layer 15 and the second electrode layer 16 are continuously formed (film formation) in the same apparatus by use of, for example, an in-line type sputtering apparatus.

Furthermore, a passivation layer 17 may be formed on the second electrode layer 16 by use of, for example, a sputtering method or the like.

(5) Next, the scribe line (scribing line) 20 is formed by irradiating the power generation layer 14, the buffer layer 15, and the second electrode layer 16 with, for example, a laser beam or the like.

Because of this, the layered body 12 is separated into a plurality of layered bodies, and a plurality of photovoltaic cells 21 having a longitudinal rectangular shape are thereby obtained.

The photovoltaic cells 21 are electrically separated from each other.

Additionally, the photovoltaic cells 21 adjacent to each other are electrically connected in series.

(6) Next, as shown in FIGS. 3D and 3E, the power generation layer 14, the buffer layer 15, and the second electrode 16 are removed by irradiating a predetermined portion of the second face 11b of the substrate 11 with a laser light r, and the laser scribe hole 30 is thereby formed.

Specifically, by scanning the second face 11b (on the first electrode layer 13) with the irradiation spot rp of the laser light r, the power generation layer 14, the buffer layer 15, and the second electrode 16 which are formed at the position corresponding to the portion thereof are removed.

The laser scribe hole 30 are arrayed in a direction parallel to the scribe line 20.

As the laser light r, for example, IR laser light is used.

By use of a laser light oscillator oscillating an infrared light, IR (InfraRed) laser light is generated, and it is possible to irradiate the second face 11b of the substrate 11 with the laser light.

The infrared light is light having a wavelength greater than 780 nm and is referred to as a heat wave.

The infrared light is light which creates a large effect of heat.

As the IR laser light, CO₂ laser light or YAG laser light (Yttrium Aluminum Garnet Laser) is used.

When YAG laser light is used, the IR laser light has a fundamental wave (a wavelength of 1064 nm), and it is possible to make the diameter of the spot rp large, such as, 60 μm or more.

When the aforementioned power generation layer 14, the buffer layer 15, the second electrode 16, and the passivation layer 17 are etched by the irradiation of the IR laser light, damages to the processed edge face rd of the layers 14, 15, 16, and 17 are generated.

Specifically, particles which are evaporated and removed from the layers 14, 15, 16, and 17 are adhered to the processed edge face rd as a result of the heat at the time of the laser light irradiation.

The foregoing particles are mainly TCO.

Additionally, the wavelength which is to be absorbed by the power generation layer 14 includes an infrared wavelength, as a result, damage, such as electro-migration or the like, is generated.

As described above, due to the damage to the processed edge face rd of the layers 14, 15, 16, and 17 being generated, a short-circuited portion in which the layers 14, 15, 16, and 17 are electrically short-circuited to each other is formed, that is, the shunt region 31 is formed.

Finally, as shown in FIG. 3F, the solar cell module 10 shown in FIGS. 1 and 2A to 2C is obtained.

In other cases, a plurality of laser scribe holes 30 are arrayed in the direction parallel to the scribe line 20 in the method for manufacturing the above-described solar cell module 10, however, the direction in which the laser scribe holes 30 are arrayed may be a direction orthogonal to the scribe line 20 or be a direction intersecting with the scribe line by a predetermined angle.

In the solar cell module 10 manufactured in the above-described manner, even when the output decreases due to occurrence of malfunction in one of the photovoltaic cells, since the shunt region which is generated around the laser scribe hole is operates as a bypass pathway, it is possible for an electrical current to flow in the bypass pathway.

Consequently, the voltage to be applied to the photovoltaic cell in which the output thereof is lowered decreases, and it is possible to prevent the photovoltaic cell in which the output thereof is lowered from being broken down.

As a result, in the solar cell module 10, the output thereof is prevented from being degraded, it is possible to prevent a hot spot phenomenon and to obtain an excellent reliability.

### EXAMPLES

Next, Examples of the invention will be described.

In the Examples, a solar cell module was manufactured in the below described manner.

Firstly, a first electrode layer was formed on the transparent substrate.

Next, each of a p-type amorphous silicon film, an i-type amorphous silicon film, and an n-type amorphous silicon film was formed on the first electrode layer in the plasma CVD reaction chamber for exclusive use to form each film, and the power generation layer was thereby formed.

Next, after the power generation layer was separated off by laser irradiation, a buffer layer and a second electrode layer were sequentially formed on the power generation layer by use of a sputtering method.

Next, a scribe line (scribing line) was formed by irradiating the first electrode layer, the power generation layer, and the second electrode layer with a laser beam.

Next, a laser scribe hole was formed so as to penetrate through the power generation layer, buffer layer, and the second electrode.

Hereinafter, conditions for forming the laser scribe hole in Examples 1 to 8 and Comparative Example will be described.

### Examples 1 to 4

The laser scribe hole was formed by use of YAG laser light (wavelength of 1064 nm). The beam diameter was 45 μm. The condition of laser light irradiation was 0.7 to 1.0 (J/cm²).

In Examples 1 to 4, a plurality of laser scribe holes were formed in a direction parallel to the scribe line.

The distance between the laser scribe holes is shown in Table 1.

### Examples 5 to 8

The laser scribe holes were formed by use of YAGSHG laser light (Aluminum Garnet Second Harmonic Generation Laser, wavelength of 532 nm). A beam diameter was 45 μm. The condition of laser light irradiation was 0.7 to 1.0 (J/cm²).

In Examples 5 to 8, a plurality of laser scribe holes were formed in a direction parallel to the scribe line.

The distance between the laser scribe holes is shown in Table 1.

### Comparative Example

In Comparative Example, the laser scribe hole were not formed.

The solar cell module of Examples 1 to 8 and the solar cell module of the Comparative Example were subjected to a hot spot test.

In a method for evaluating each of the solar cell modules, the FF value which is obtained before a hot spot tolerance test under IEC-61646 (2008) (hereinafter, refer to HS test) is performed is compared with the FF value which is obtained after the HS test is performed. The evaluation result is shown in Table 1.

TABLE 1

| | | BEAM | DISTANCE | RANGE OF FF VALUE | |
|---|---|---|---|---|---|
| | TYPE OF | DIAMETER | BETWEEN DOTS | INITIAL | AFTER HS |
| | LASER | [μm] | [μm] | VALUE | TEST |
| EXAMPLE 1 | YAG | 45 | 50 | 0.65-0.73 | 0.6-0.7 |
| EXAMPLE 2 | YAG | 45 | 100 | 0.65-0.73 | 0.6-0.68 |
| EXAMPLE 3 | YAG | 45 | 200 | 0.65-0.73 | 0.6-0.68 |
| EXAMPLE 4 | YAG | 45 | 500 | 0.65-0.73 | 0.6-0.65 |
| EXAMPLE 5 | YAGSHG | 45 | 50 | 0.65-0.73 | 0.6-0.7 |
| EXAMPLE 6 | YAGSHG | 45 | 100 | 0.65-0.73 | 0.6-0.68 |
| EXAMPLE 7 | YAGSHG | 45 | 200 | 0.65-0.73 | 0.6-0.68 |
| EXAMPLE 8 | YAGSHG | 45 | 500 | 0.65-0.73 | 0.6-0.65 |
| COMPARATIVE | NONE | — | — | 0.65-0.73 | 0.45-0.6 |
| EXAMPLE | | | | | |

As evidenced by Table 1, regarding the solar cell module of the Comparative Example in which the laser scribe holes were not formed, when the FF value (initial value) which is obtained before the HS test is performed is compared with the FF value which is obtained after the HS test is performed, it is confirmed that the FF value is significantly degraded.

In contrast, regarding the solar cell module of Examples 1 to 8 in which the laser scribe holes were formed, when the FF value (initial value) which is obtained before the HS test is performed is compared with the FF value which is obtained after the HS test is performed, it is confirmed that degradation of the FF value is considerably suppressed.

As described above, degradation of the FF value can be considerably suppressed in Examples 1 to 8. It is thought that, this is because the shunt region that is generated around the laser scribe hole functions as a bypass pathway.

As described above, a solar cell module and a method for manufacturing the solar cell module related to the invention are described, but the technical scope of the invention is not limited to the above embodiments, but various modifications may be made without departing from the scope of the invention.

In the aforementioned solar cell module, for example, a single cell structure having a single power generation layer is adopted and illustrated as a module structure. However, the invention is not limited to the structure.

The structure of the invention can be also applied to a multi-junction cell in which a plurality of power generation layers are layered.

### INDUSTRIAL APPLICABILITY

The invention is widely applicable to a solar cell module and a solar cell manufacturing method.

What is claimed is:

1. A solar cell module comprising:
a plurality of photovoltaic cells including a layered body in which a first electrode layer, a power generation layer, and a second electrode layer are layered in series, the photovoltaic cells being electrically connected with each other in series;
a scribe line separating the photovoltaic cells that are adjacent to each other in the photovoltaic cells;
a scribe hole that is formed so as to penetrate through the power generation layer and the second electrode layer; and
a bypass pathway that is formed of a shunt region, the shunt region being generated at a periphery of the scribe hole.

2. The solar cell module according to claim 1, further comprising:
a plurality of scribe holes that are formed so as to penetrate through the power generation layer and the second electrode layer.

3. A solar cell module manufacturing method comprising:
forming a layered body in which a first electrode layer, a power generation layer, and a second electrode layer are layered in series on a substrate;
forming a plurality of photovoltaic cells which are electrically connected in series by forming a scribe line;
forming a scribe hole that penetrates through the power generation layer and the second electrode by irradiating a part of the power generation layer and the second electrode layer with a laser light; and
forming a bypass pathway including a shunt region which is generated at a processed edge face of the power generation layer and the second electrode layer using heat, the heat being generated at the time of the laser light irradiation.
